(19) United States
(12) Patent Application Publication
(10) Pub. No.: US 2018/0312627 A1
(43) Pub. Date: Nov. 1, 2018

(54) Resin Composition, Prepreg, Metal-Clad Laminate, and Printed Circuit Board Using the Same

(71) Applicant: TAIWAN UNION TECHNOLOGY CORPORATION, Chupei City (TW)

(72) Inventors: Chih-Wei LIAO, Chupei City (TW); Guan-Syun TZENG, Chupei City (TW); Ju-Ming HUANG, Chupei City (TW); Chang-Chien YANG, Chupei City (TW)

(21) Appl. No.: 15/667,392

(22) Filed: Aug. 2, 2017

(30) Foreign Application Priority Data
Apr. 27, 2017 (TW) 106114102

(51) Int. Cl. C08G 59/42; C08J 5/24; C08K 5/5333; C08K 3/36; H05K 1/03; H05K 3/46

(52) U.S. Cl. CPC C08G 59/4223; C08J 5/24; C08K 5/5333; C08J 2363/00; H05K 1/0373; H05K 3/4644; C08K 3/36

(57) ABSTRACT

A resin composition is provided. The resin composition comprises an epoxy resin with at least two epoxy groups in each molecule, and a first hardener of the following formula (I):

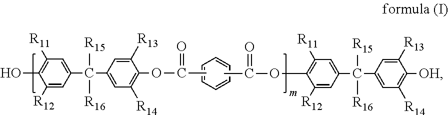

wherein R₁₁, R₁₂, R₁₃, R₁₄, R₁₅, R₁₆, and n are as defined in the specification.

### CLAIM FOR PRIORITY

This application claims the benefit of Taiwan Patent Application No. 106114102 filed on Apr. 27, 2017, the subject matters of which are incorporated herein in their entirety by reference.

### BACKGROUND OF THE INVENTION

### Field of the Invention

The present invention relates to a resin composition, especially a resin composition that can provide an electronic material with outstanding heat resistance. The resin composition of the present invention can be used in combination with glass fibers to constitute a composite material or prepreg, and furthermore can be used as a metal foil adhesive to manufacture a metal-clad laminate and a printed circuit board.

The present invention provides a new resin composition which uses both epoxy resin and a first hardener with a specific structure. When cured, the resin composition can provide an electronic material with good electrical properties and heat resistance, especially high glass transition temperature (Tg). In some embodiments, the resin composition further comprises an oligomeric phosphonate resin, which contains phosphorus, and therefore, can impart not only good electrical properties but also flame retardance to the resin composition and the cured product of the resin composition. The present invention can thus provide an electronic material with good electrical properties and physicochemical properties.

### Descriptions of the Related Art

There are strict requirements on the physicochemical properties of electronic materials because electronic products need to be miniature, lightweight and dense. Conventional electronic materials are failing to keep up with the trends of high-frequency and high-speed signal transmission, miniaturization of electronic elements, and high-density wiring of PCBs. For example, electronic materials with acceptable electrical properties usually have poor peeling strength. Some electronic materials with both acceptable electrical properties and peeling strength have insufficient glass transition temperature and heat resistance. Therefore, there is a need for an electronic material which has a low Dk and Df value, good peeling strength, high glass transition temperature and good heat resistance.

### SUMMARY OF THE INVENTION

In view of the aforementioned disadvantages of conventional electronic materials, the present invention provides a resin composition and an electronic material prepared using the same. The prepared electronic material has good electrical properties, high glass transition temperature, high peeling strength, and good flame retardance.

As described in the following objectives of the present invention, the technical means of the present invention is to use a hardener with a specific structure together with epoxy resin to provide an electronic material with the aforementioned advantages.

An objective of the present invention is to provide a resin composition, comprising the following: an epoxy resin with at least two epoxy groups in each molecule; and a first hardener, which has the structure of formula (I):

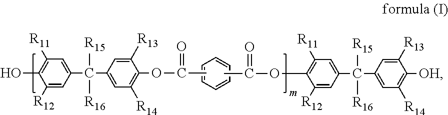

wherein, R₁₁, R₁₂, R₁₃, R₁₄, R₁₅ and R₁₆ are independently H, halogen, a C₁ to C₂₀ aliphatic hydrocarbyl group, a C₃ to C₂₀ alicyclic hydrocarbyl group, or a C₆ to C₂₀ aromatic hydrocarbyl group, and m is an integer from 1 to 10.

In some embodiments of the present invention, R₁₁, R₁₂, R₁₃, R₁₄, R₁₅ and R₁₆ in formula (I) are independently H, halogen, a C₁ to C₁₀ alkyl group, a C₃ to C₁₀ cycloalkyl group, or a C₆ to C₁₄ aromatic hydrocarbyl group. For example, R₁₁, R₁₂, R₁₃ and R₁₄ are each H, and R₁₅ and R₁₆ are each a methyl group.

In some embodiments of the present invention, the molar ratio of epoxy groups to the reactive functional group of the first hardener is from about 1:0.8 to about 1:1.6, and preferably from about 1:1.2 to about 1:1.6.

In some embodiments of the present invention, the resin composition further comprises an oligomeric phosphonate of formula (II):

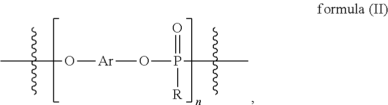

wherein, Ar is an aromatic group, and the —O—Ar—O— is a residue derived from a diphenol; R is a C₁ to C₂₀ alkyl group, a C₂ to C₂₀ alkenyl group, a C₂ to C₂₀ alkynyl group, a C₃ to C₂₀ cycloalkyl group, or a C₆ to C₂₀ aryl group; and n is an integer from 1 to 20. The diphenol may be selected from the group consisting of resorcinol, hydroquinone, bisphenol A, bisphenol F, bisphenol S, 4,4′-thiodiphenol, oxydiphenol, phenolphthalein, 4,4′-(3,3,5-trimethyl-cyclohexane-1,1-diyl) diphenol, and combinations thereof.

In some embodiments of the present invention, the oligomeric phosphonate has the structural of formula (III);

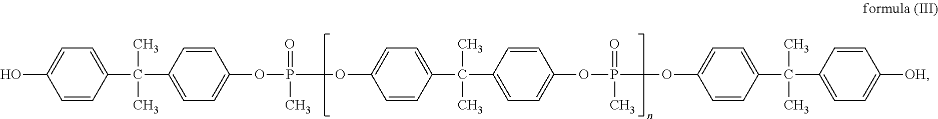

wherein n is an integer of from 1 to 10.

In some embodiments of the present invention, the resin composition further comprises a second hardener selected from the group consisting of cyanate ester resin, benzoxazine resin, phenol novolac resins (PN), styrene maleic anhydride resin (SMA), dicyandiamide (Dicy), diaminodiphenyl sulfone (DDS), amino triazine novolac resin (ATN), diaminodiphenylmethane, poly(styrene-co-vinyl phenol), and combinations thereof.

In some embodiments of the present invention, the resin composition further comprises a catalyst, which is an imidazole compound, a pyridine compound, or a combination thereof.

In some embodiments of the present invention, the resin composition further comprises a filler selected from the group consisting of silicon dioxide, aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartzs, diamonds, diamond-like, graphite, calcined kaolin, pryan, mica, hydrotalcite, hollow silicon dioxide, polytetrafluoroethylene (PTFE) powders, glass beads, ceramic whiskers, carbon nanotubes, nanosized inorganic powders, and combinations thereof.

In some embodiments of the present invention, the resin composition further comprises a dispersant agent, a toughener, a flame retardant, or a combination of any two or more of the foregoing.

Another objective of the present invention is to provide a prepreg, which is prepared by impregnating a substrate into the above-mentioned resin composition or by coating the above-mentioned resin composition onto a substrate, and drying the impregnated or coated substrate.

Yet another object of the present invention is to provide a metal-clad laminate, which is prepared from the above-mentioned prepreg, or by directly coating the above-mentioned resin composition onto a metal foil and drying the coated metal foil.

Yet another objective of the present invention is to provide a printed circuit board, which is prepared from the above-mentioned metal-clad laminate.

To render the above objectives, the technical features and advantages of the present invention more apparent, the present invention will be described in detail with reference to some embodiments hereinafter.

### BRIEF DESCRIPTION OF THE DRAWINGS

Not applicable.

### DESCRIPTION OF THE PREFERRED EMBODIMENT

Hereinafter, some embodiments of the present invention will be described in detail. However, without departing from the spirit of the present invention, the present invention may be embodied in various embodiments and should not be limited to the embodiments described in the specification. Furthermore, for clarity, the size of each element and each area may be exaggerated in the appended drawings and not depicted in actual proportion. Unless it is additionally explained, the expressions “a,” “the,” or the like recited in the specification (especially in the claims) should include both the singular and the plural forms. Furthermore, unless it is additionally explained, while describing the constituents in the solution, mixture and composition in the specification, the amount of each constituent is calculated based on the dry weight, i.e., regardless of the weight of the solvent.

The inventive efficacy of the present invention lies in providing a resin composition which uses epoxy resin together with a first hardener that has a specific structure and is capable of improving the physical properties (e.g., heat resistance and peeling strength) of the laminate prepared therefrom without sacrificing the electrical properties of the laminate (i.e., without raising the Dk and Df values of the laminate).

Resin Composition

The resin composition of the present invention comprises an epoxy resin and a first hardener. The detailed descriptions for each component of the resin composition are provided below.

[Epoxy Resin]

As used herein, an epoxy resin refers to a thermosetting resin with at least two epoxy functional groups in each molecule, such as a multi-functional epoxy resin, a linear phenolic epoxy resin, or a combination thereof. Examples of the multi-functional epoxy resin include a bifunctional epoxy resin, a tetrafunctional epoxy resin, an octafunctional epoxy resin, and the like. Specific examples of the epoxy resin include but are not limited to phenol phenolic-type epoxy resins, bisphenol A-type epoxy resins, bisphenol F-type epoxy resins, bisphenol S-type epoxy resins, cresol phenolic-type epoxy resin, bisphenol A phenolic-type epoxy resin, bisphenol F phenolic-type epoxy resins, diphenylethylene-type epoxy resins, triazine skeleton-containing epoxy resins, fluorene skeleton-containing epoxy resins, tri(4-hydroxyphenyl)methane-type epoxy resins, biphenyl-type epoxy resins, xylylene-type epoxy resins, biphenyl aralkyl-type epoxy resins, naphthalene-type epoxy resins, dicyclopentadiene-type (DCPD-type) epoxy resins, and alicyclic epoxy resins. Examples of the epoxy resin also include diglycidyl ether compounds of multi-ring aromatics such as multi-functional phenols and anthracenes. Furthermore, phosphorous may be introduced into the epoxy resin to provide a phosphorous-containing epoxy resin.

The above-mentioned epoxy resins can either be used alone or in combination depending on the need of persons with ordinary skill in the art. In some embodiments of the present invention, phenol phenolic-type epoxy resins and dicyclopentadiene-type epoxy resins are used.

[First Hardener]

The first hardener has the structure of the following formula (I):

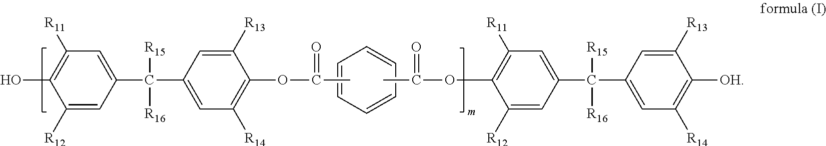

In formula (I), R₁₁, R₁₂, R₁₃, R₁₄, R₁₅ and R₁₆ are independently H, halogen, a C₁ to C₂₀ aliphatic hydrocarbyl group, a C₃ to C₂₀ alicyclic hydrocarbyl group, or a C₆ to C₂₀ aromatic hydrocarbyl group, and m is an integer from 1 to 10. Examples of halogen include F, Cl, Br, and I, and F, Cl and Br are preferred. Examples of the aliphatic hydrocarbyl group include but are not limited to an alkyl group, such as methyl, ethyl, propyl, butyl, pentyl, hexyl, heptyl, octyl, nonyl or decyl group, and an alkenyl group such as vinyl or allyl, and a C₁ to C₁₀ alkyl group is preferred. The alicyclic hydrocarbyl group is preferably a C₃ to C₁₀ cycloalkyl group. Examples of the C₃ to C₁₀ cycloalkyl group include but are not limited to cyclopropyl, cyclobutyl, cyclopentyl, cyclohexyl, cycloheptyl, cyclooctyl, cyclononyl and cyclodecyl. The aromatic hydrocarbyl group is preferably a C₆ to C₁₄ aromatic group. Examples of the C₆ to C₁₄ aromatic group include but are not limited to phenyl, naphthyl and anthranyl. In the preferred embodiments of the present invention, R₁₁, R₁₂, R₁₃, and R₁₄ are each H, halogen, or a C₁ to C₁₀ alkyl group, and R₁₅ and R₁₆ are each H, halogen, or a C₁ to C₁₀ alkyl group, especially a C₁ to C₃ alkyl group.

The preparation method of the first hardener of formula (I) is not particularly iced. The first hardener of formula (I) can be prepared by, for example, polymerizing an aromatic dicarboxylic acid (or a derivative thereof) with a bisphenol compound (or a derivative thereof). The polymerization reaction can be carried out by any of the methods known in this field, including solution polymerization, interfacial polymerization and melt polymerization.

Examples of the aromatic dicarboxylic acid include, but are not limited to, terephthalic acid, isophthalic acid, phthalic acid, chlorophthalic acid, nitrophthalic acid, 2,5-naphthalenedicarboxylic acid, 2,6-naphthalenedicarboxylic acid, 2,7-naphthalenedicarboxylic acid, 1,5-naphthalenedicarboxylic acid, methylterephthalic acid, 4,4′-biphenyldicarboxylic acid, 2,2′-biphenyldicarboxylic acid, 4,4′-diphenyl ether dicarboxylic acid, 4,4′-diphenyl methane dicarboxylic acid, 4,4′-diphenyl sulfone dicarboxylic acid, 4,4′-isopropylidene dicarboxylic acid, 1,2-bis(4-carboxyphenoxy)ethane, and sodium isophthalic acid-5-sulfonate. The aromatic dicarboxylic acid is preferably terephthalic acid or isophthalic acid and more preferably a combination of terephthalic acid and isophthalic acid.

Examples of the bisphenol compound include but are not limited to bis(4-hydroxyphenyl)phenylmethane, 1,1-bis(4-hydroxyphenyl)-1-phenylethane (BPAP), 1,1-bis(4-hydroxy-3-methylphenyl)-1-phenylethane, 1,1-bis(4-hydroxy-3,5-dimethylphenyl)-1-phenylethane, 1,1-bis(4-hydroxy-3,5-dibromophenyl)-1-phenylethane, 1,1-bis(4-hydroxy-3-phenyl-phenyl)-1-phenylethane, 2,2-bis(4-hydroxyphenyl)propane (BPA), 2,2-bis(4-hydroxy-3,5-dimethylphenyl)propane, 2,2-bis(4-hydroxy-3-methylphenyl)propane (BPC), 2,2-bis(4-hydroxy-3,5-dibromophenyl)propane, and 2,2-bis(4-hydroxy-3,5-dichlorophenyl)propane. The bisphenol compound is preferably 2,2-bis(4-hydroxyphenyl)propane, 2,2-bis(4-hydroxy-3,5-dimethylphenyl)propane, 2,2-bis(4-hydroxy-3-methylphenyl)propane, 2,2-bis(4-hydroxy-3,5-dibromophenyl)propane, or 2,2-bis(4-hydroxy-3,5-dichlorophenyl)propane.

The above-mentioned aromatic dicarboxylic acids and the bisphenol compound and their derivatives can either be used alone or in combination. In some embodiments of the present invention, the first hardener is obtained by reacting 2,2-bis(4-hydroxyphenyl)propane (BPA) with terephthalic acid and/or isophthalic acid, wherein R₁₁, R₁₂, R₁₃ and R₁₄ in formula (I) are each H, and R₁₅ and R₁₆ in formula (I) are each methyl.

In the resin composition of the present invention, the amount of the epoxy resin and the first hardener depends on the molar ratio of the epoxy group of the epoxy resin to the reactive functional group of the first hardener. Specifically, the mole ratio of the epoxy group of the epoxy resin to the reactive functional group of the first hardener is from about 1:0.8 to about 1:1.6. In particular, as illustrated in the appended embodiments, when the molar ratio of the epoxy group of the epoxy resin to the reactive functional group of the first hardener is from about 1:1.2 to about 1:1.6, the glass transition temperature (Tg) of the material prepared by using the resin composition is better and significantly higher than that of the embodiment using another hardener.

[Optional Components]

The resin composition of the present invention may optionally further comprise other ingredients, such as the oligomeric phosphonate described below, a second hardener, and additives well-known to persons with ordinary skill in the art, to improve the physicochemical properties of the resultant electronic material or the workability of the resin composition during manufacturing.

<Oligomeric Phosphonate>

The present invention also features in that the resin composition may further comprise the oligomeric phosphonate of the following formula (II):

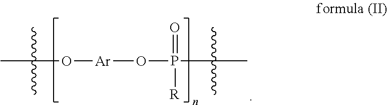

In formula (II), Ar is an aromatic group, and the —O—Ar—O— is a residue derived from a diphenol, such as resorcinol, hydroquinone, bisphenol A, bisphenol F, bisphenol S, 4,4′-thiodiphenol, dihydroxy diphenyl ether, phenolphthalein, or 4,4′-(3,3,5-trimethyl-cyclohexane-1,1-diyl) diphenol; R is a C₁ to C₂₀ alkyl group, a C₂ to C₂₀ alkenyl group, a C₂ to C₂₀ alkynyl group, a C₃ to C₂₀ cycloalkyl group, or a C₆ to C₂₀ aryl group; and n is an integer from 1 to 20, such as an integer from 1 to 15, 1 to 10 or 1 to 5. Examples of the C₁ to C₂₀ alkyl groups include but are not limited to methyl, ethyl, n-propyl, isopropyl, n-butyl and isobutyl. Examples of C₂ to C₂₀ alkenyl groups include but are not limited to vinyl, allyl, but-1-enyl and but-2-enyl. Examples of the C₂ to C₂₀ alkynyl groups include but are not limited to ethynyl and prop-1-ynyl. Examples of the C₃ to C₂₀ cycloalkyl groups include but are not limited to cyclopropyl, cyclobutyl, cyclopentyl and cyclohexyl. Examples of the C₆ to C₂₀ aryl groups include but are not limited to phenyl, naphthyl, and anthranyl.

In some embodiments of the present invention, the oligomeric phosphonate has the structure of the following formula (III):

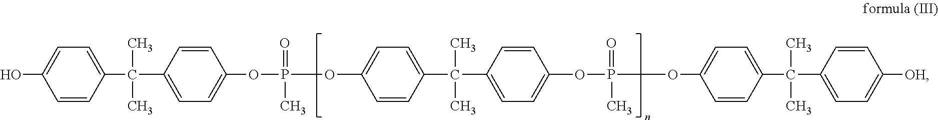

wherein n is an integer from 1 to 10.

The oligomeric phosphonate contains phosphorus and thus can provide flame retardance to the resin composition. Furthermore, conventional additive-type flame retardants cannot crosslink with other components of the resin composition, but the oligomeric phosphonate may have reactive end group(s) (e.g. hydroxyl groups) and therefore, is capable of crosslinking with other components of the resin composition to thereby achieve preferred physical properties such as mechanical strength and heat resistance. It has been found that the oligomeric phosphonate can provide excellent electrical properties and peeling strength.

In the resin composition of the present invention, when the oligomeric phosphonate is used, the weight ratio of the first hardener to the oligomeric phosphonate is preferably from about 4:1 to about 2:1. It has been found that when the content of the oligomeric phosphonate is too low, such as lower than the above-specified range, the flame retardance of the electronic material prepared from the resin composition is poor (e.g., unable to achieve UL 94 V0). When the content of oligomeric phosphonate and the phosphorus content (P %) are higher than the above-specified range, the water absorption performance and the glass transition temperature of the electronic material prepared from the resin composition are poor.

<Second Hardener>

The second hardener can be any hardener suitable for epoxy resin, such as a compound containing —OH group(s), a compound containing amino group(s), an anhydride compound, and an active ester compound. The amount of the second hardener is not particularly limited, it can be adjusted depending on the need of persons with ordinary skill in the art. Examples of the second hardener include but are not limited to a cyanate ester resin, a benzoxazine resin, a phenol novolac resin (PN), a styrene maleic anhydride resin (SMA), dicyandiamide (Dicy), diaminodiphenyl sulfone (DDS), diaminodiphenylmethane, poly(styrene-co-vinyl phenol), and combinations thereof. In some embodiments of the present invention, the second hardener is a cyanate ester resin, a benzoxazine resin or a combination thereof.

The cyanate ester resin refers to a chemical substance based on a bisphenol or phenolic derivative, in which the hydrogen atom of at least one OH group of the derivative is substituted by a cyanide group. Cyanate ester resin usually has —OCN group(s) and can form trimers through crosslinking reaction. Examples of the cyanate ester resin include but are not limited to 4,4′-ethylidenebisplienylene cyanate, 4,4′-dicyanatobiphenyl 2,2-bis(4-cyanatophenyl)propane, bis(4-cyanato-3,5-dimethylphentyl)methane, bis(4-cyanatophenyl)thioether, bis(4-cyanatophenyl)ether, prepolymer of bisphenol A dicyanate in methyl ethyl ketone, 1,1-bis(4-cyanatophenyl)ethane, 1,1-bis(4-cyanatophenyl)methane, 1,3-bis [4-cyanatophenyl-1-(methylethylidene)]benzene, bis(4-cyanatophenyl)ether, bis(4-cyanatophenyl)-2,2-butane, 1,3-bis [2-(4-cyanatophenyl)propyl]benzene, tris(4-cyanatophenyl)ethane, cyanated novolak, and cyanated phenoldicyclopentadiene adduct.

Benzoxazine resin refers to a chemical substance prepared by a phenolic hydroxy compound, a primary amine and a formaldehyde according to the following reaction.

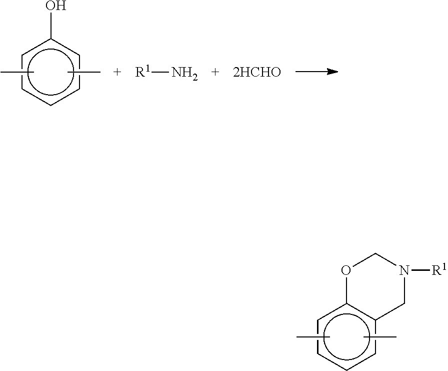

In the above reaction equation, examples of the phenolic hydroxy compound include but are not limited to multi-functional phenol compounds (e.g., catechol, resorcinol, or hydroquinone), biphenol compounds, bisphenol compounds (such as bisphenol A, bisphenol F, or bisphenol S), trisphenol compound, and a phenolic resin (e.g. novolac varnish resin or melamine phenolic resin). The R¹ group of the primary amine (R′—NH₂) can be an alkyl group, a cycloalkyl group, an un-substituted phenyl group, or a phenyl group substituted by an alkyl group or alkoxy group. Examples of the primary amine include but are not limited to methylamine and substituted or unsubstituted aniline. Formaldehyde (HCHO) can be provided by formalin or paraformaldehyde.

The benzoxazine resin can be added into the resin composition of the present invention in the form of its prepolymer by conducting a ring-opening polymerization in advance. The preparation and use of such prepolymer can be found in, for example, US 2012/0097437 A1 (Applicant: Taiwan Union Technology Corporation), the full text of which is incorporated herein in its entirety by reference.

In general, based on the dry weight of the resin composition, the amount of the second hardener ranges from about 5 wt % to about 25 wt %, such as about 6 wt %, about 7%, about 8%, about 9 wt %, about 10 wt %, about 12 wt %, about 14 wt %, about 16 wt %, about 18 wt %, about 20 wt %, or about 22 wt %, but the present invention is not limited thereto. The amount of the seconder hardeners can still be adjusted depending on the need of persons with ordinary skill in the art.

<Additive>

The resin composition of the present invention may optionally further comprise other additives well-known to persons with ordinary skill in the art. Examples of such additives include but are not limited to a catalyst, a filler, a dispersant agent, a toughener, and a flame retardant. The additives can be used alone or in combination.

In some embodiments of the present invention, the resin composition further comprises a catalyst that promotes the reaction of epoxy functional groups and lowers the curing reaction temperature of the resin composition. The species of the catalyst is not particularly limited as long as it can promote the ring-opening reaction of epoxy functional groups and lower the curing reaction temperature. For example, the catalyst can be a tertiary amine, a quaternary ammonium salt, a imidazole compound, or a pyridine compound, and each of the aforementioned catalyst can either be used alone or in combination. Examples of the catalyst include, but are not limited to, 2-methylimidazole, 2-ethyl-4-methylimidazole, 2-phenylimidazole, dimethylbenzylamine, 2-dimethylaminomethylphenol, 2,4,6-tris(dimethylaminomethyl)phenol, 2,3-diaminopyridine, 2,5-diaminopyridine, 2,6-diaminopyridine, 4-dimethylaminopyridine, 2-amino-3-methylpyridine, 2-amino-4-methylpyridine, and 2-amino-3-nitropyridine. In general, based on the dry weight of the resin composition, the amount of the catalyst ranges from about 0.5 wt % to about 5 wt %, such as about 1 wt %, about 1.5 wt %, about 2 wt %, about 2.5 wt %, about 3 wt %, about 3.5 wt %, about 4 wt %, or about 4.5 wt %, but the present invention is not limited thereto. The amount of the catalyst can be adjusted depending on the need of persons with ordinary skill in the art.

In some embodiments of the present invention, the resin composition further comprises a filler. Examples of the filler include but are not limited to the organic or inorganic fillers selected from the group consisting of silicon dioxide, aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartzs, diamonds, diamond-like, graphite, calcined kaolin, pryan, mica, hydrotalcite, hollow silicon dioxide, polytetrafluoroethylene (PTFE) powders, glass beads, ceramic whiskers, carbon nanotubes, nanosized inorganic powders, and combinations thereof. In general, based on the dry weight of the resin composition, the amount of the filler ranges from 0 wt % to 40 wt %, such as about 1 wt %, about 3 wt %, about 5 wt %, about 7 wt %, about 10 wt %, about 15 wt %, about 20 wt %, about 25 wt %, about 30 wt %, or about 35 wt %, but the present invention is not limited thereto. The amount of the filler can be adjusted depending on the need of persons with ordinary skill in the art.

Preparation of Resin Composition

The resin composition of the present invention may be prepared into a varnish for subsequent applications by evenly mixing the epoxy resin, the first hardener and other optional components through a stirrer and dissolving or dispersing the obtained mixture into a solvent. The solvent here can be any inert solvent that can dissolve or disperse the components of the resin composition of the present invention, but does not react with the components of the resin composition. Examples of the solvent that can dissolve or disperse the components of the resin composition include but are not limited to toluene, γ-butyrolactone, methyl ethyl ketone, cyclohexanone, butanone, acetone, xylene, methyl isobutyl ketone, N,N-dimethylformamide (DMF), N,N-dimethylacetamide (DMAc), and N-methylpyrolidone (NMP). The solvents can either be used alone or in combination. The amount of the solvent is not particularly limited as long as the components of the resin composition can be evenly dissolved or dispersed therein. In some embodiments of the present invention, a mixture of toluene, methyl ethyl ketone and γ-butyrolactone is used as the solvent.

Prepreg

The present invention also provides a prepreg prepared from the above-mentioned resin composition, wherein the prepreg is prepared by impregnating a substrate with the above-mentioned resin composition or by coating the above-mentioned resin composition onto a substrate and drying the impregnated or coated substrate. Examples of the substrate include but are not limited to glass fiber reinforcing material (e.g., glass-fiber woven fabrics or non-woven fabrics, glass papers, or glass mats), kraft papers, short fiber cotton papers, nature fiber cloths, and organic fiber cloths (e.g., cloths of liquid crystal polymer fiber). In some embodiments of the present invention, 2116 glass fiber cloth are used as the substrate, and the substrate is heated and dried at 175° C. for 2 to 15 minutes (B-stage) to provide a semi-cured prepreg.

Metal-Clad Laminate and Printed Circuit Board

The present invention also provides a metal-clad laminate prepared from the abovementioned resin composition or prepreg. The metal-clad laminate comprises a dielectric layer and a metal layer. The dielectric layer is provided by the abovementioned prepreg or just the cured product of the resin composition. Specifically, the metal-clad laminate can be prepared by superimposing a plurality of prepregs and superimposing a metal foil (such as a copper foil) on at least one external surface of the dielectric layer composed of the superimposed prepregs to provide a superimposed object, and performing a hot-pressing operation onto the superimposed object to obtain the metal-clad laminate. Alternatively, the metal-clad laminate can be prepared by directly coating the resin composition onto a metal foil and drying the coated metal foil to obtain the metal-clad laminate. Furthermore, a printed circuit board can be prepared by patterning the external metal foil of the metal-clad laminate.

The present invention is further illustrated by the embodiments hereinafter, wherein the measuring instruments and methods are respectively as follows:

[Gel Time Test]

The gel time test is carried out by getting 0.2 g of the resin composition as a sample, subjecting the sample to form a disc (2 cm² in area) on a hot plate at 171° C., and calculating the time required for stirring the sample with a stirring rod until it does not adhere to the stirring rod or until it is going to be cured. The time required is regarded as the gel time.

[Water Absorption Test]

The moisture resistance of the metal-clad laminate is tested by a pressure cooker test (PCT), i.e., subjecting the metal-clad laminate into a pressure container (121° C., saturated relative humidity (100% R.H.) and 1.2 atm) for 2 hours.

[Solder Resistance Test]

The solder resistance test is carried out by immersing the dried metal-clad laminate in a solder bath at 288° C. for a certain period and observing whether there is any defect such as delamination or blistering.

[Peeling Strength Test]

The peeling strength refers to the bonding strength between the metal foil and hot-pressed laminated prepreg, which is usually expressed by the force required for vertically peeling the clad copper foil with a width of ⅛ inch from the surface of the hot-pressed laminated prepreg.

[Glass Transition Temperature (Tg) Test]

The glass transition temperature (Tg) is measured by using a Differential Scanning calorimeter (DSC), wherein the measuring methods are IPC-TM-650.2.4.25C and 24C testing method of the Institute for Interconnecting and Packaging Electronic Circuits (IPC).

[Thermal Decomposition Temperature (Td) Test]

The thermal decomposition temperature test is carried out by using a ThermoGravimetric Analysis (TGA). The programmed heating rate is 10° C. per minute. The thermal decomposition temperature was a temperature at which the weight of the sample decreased by 5% from the initial weight. The measuring methods are IPC-TM-650.2.4.24.6 testing methods of the Institute for Interconnecting and Packaging Electronic Circuits (IPC).

[Flame Retardance Test]

The flame retardance test is carried out according to UL94V (Vertical Burn), which comprises the burning of a laminate, which is held vertically, using a Bunsen burner to compare its self-extinguishing properties and combustion-supporting properties. The ranking for the flame retardance level is V0>V1>V2.

[Dielectric Constant (Dk) and Dissipation Factor (Df) Measurement]

The dielectric constant (Dk) and dissipation factor (Df) are measured according to ASTM D150 under an operating frequency of 10 GHz. The resin content (RC) of the tested prepreg is about 70%.

### EXAMPLES

Raw Material List:

| Model No. | Description |
|---|---|
| PNE-177 | Epoxy resin, available from Chang Chun (CCP) Company |
| DNE-260 | Epoxy resin, available from Chang Chun (CCP) Company |
| V575 | First hardener, available from Unitika Company |
| OL-3001 | Oligomeric phosphonate, available from FRX Company |
| HPC-8000- | DCPD type ester hardener, available from DIC Company |
| 65T | (solid content: 65%) |
| BA-230S | Cyanate ester resin, available from Lonza Company |
| PF-3500 | Benzoxazine resin, available from Chang Chun (CCP) |
| | Company |
| 525ARI | SiO₂ filler, available from Sibelco Company |
| DMAP | Catalyst, available from Union Chemical Company |
| Zinc | Zinc (catalyst), available from Union Chemical Company |

### Embodiment 1: Effect of the First Hardener

The resin compositions of Examples 1-1 to 1-4 and Comparative Examples 1-1 to 1-3 were prepared according to the constitutions shown in Table 1. Each component was mixed under room temperature with a stirrer, followed by adding toluene, methyl ethyl ketone, and γ-butyrolactone (all available from Fluka Company) thereinto. After stirring the resultant mixture under room temperature for 60 to 120 minutes, the resin compositions were obtained.

The prepregs and metal-clad laminates of Examples 1-1 to 1-4 and Comparative Examples 1-1 to 1-3 were respectively prepared by using the prepared resin compositions. In detail, one of the resin compositions of Examples 1-1 to 1-4 and Comparative Examples 1-1 to 1-3 was coated on glass fiber cloths (type: 2116; thickness: 0.08 mm) by a roller with a controlled thickness. The coated glass fiber cloths were then placed in an oven and dried at 175° C. for 2 to 15 minutes to produce prepregs in a half-cured state (B-stage) (the resin content of the prepreg was about 70%). Four pieces of the prepregs were superimposed and two sheets of copper foil (0.5 oz.) were respectively superimposed on both of the two external surfaces of the superimposed prepregs to provide a superimposed object. A hot-pressing operation was performed on each of the prepared objects. The hot-pressing conditions are as follows: raising the temperature to about 200° C. to 220° C. with a heating rate of 3.0° C./min, and hot-pressing for 180 minutes under a full pressure of 15 kg/cm² (initial pressure is 8 kg/cm²) at said temperature.

The properties of the prepregs and metal-clad laminates of Examples 1-1 to 1-4 and Comparative Examples 1-1 to 1-3, including solder resistance, peeling strength, glass transition temperature (Tg) thermal decomposition temperature (Td), dielectric constant (Dk) and dissipation factor (Df), were measured according to the aforementioned testing methods, and the results are tabulated in Table 1.

TABLE 1

| | | | | | | Comparative | Comparative | Comparative |
|---|---|---|---|---|---|---|---|---|
| | | Example | Example | Example | Example | Example | Example | Example |
| Unit: Parts by weight | | 1-1 | 1-2 | 1-3 | 1-4 | 1-1 | 1-2 | 1-3 |
| Epoxy resin | PNE-177 | 84.8 | 63.6 | 63.6 | 63.6 | 84.7 | 84.7 | 84.7 |
| First hardener | V575 | 67.2 | 75.6 | 100.8 | 126.2 | — | — | — |
| DCPD type | HPC-8000-65T | — | — | — | — | 115.2 | 172.8 | 230.2 |
| ester hardener | | | | | | | | |
| Catalyst | DMAP | 0.075 | 0.075 | 0.075 | 0.075 | 0.135 | 0.135 | 0.135 |

| | | | | | | | |
|---|---|---|---|---|---|---|---|
| Molar ratio (epoxy group of | 1:0.8 | 1:1.2 | 1:1.6 | 1:2 | 1:0.8 | 1:1.2 | 1:1.6 |
| epoxy resin:reactive | | | | | | | |
| functional group of first | | | | | | | |
| hardener or DCPD type | | | | | | | |
| ester hardener) | | | | | | | |
| Gel time (S/G; sec) | 354 | 377 | 382 | 412 | 334 | 360 | 417 |
| Characteristics (Units) | | | | | | | |
| Solder resistance (min) | >20 | >20 | >20 | >20 | >20 | >20 | >20 |
| Peeling strength (lb/inch) | 5.1 | 5.2 | 5.2 | 5.27 | 4.7 | 5.1 | 4.9 |
| DSC Tg (° C.) | 165 | 198 | 202 | 200 | 155 | 161 | 148 |
| Td 5% (° C.) | 386 | 385 | 385 | 386 | 385 | 385 | 386 |
| DK @ 10 GHz (RC: 70%) | 3.6 | 3.6 | 3.6 | 3.6 | 3.7 | 3.7 | 3.7 |
| Df @ 10 GHz (RC: 70%) | 0.016 | 0.014 | 0.014 | 0.014 | 0.017 | 0.016 | 0.016 |

As shown in Table 1, the properties of the electronic materials of Examples 1-1 to 1-4 are superior to those of the electronic materials of Comparative Examples 1-1 to 1-3. In particular, when the mole ratio of the epoxy group of the epoxy resin to the reactive functional group of the first hardener is greater than 1:1.2, the glass transition temperature of the electronic material is 200° C. or higher and significantly higher than that of Comparative Examples 1-1 to 1-3 using DCPD type ester hardener. In addition, once the mole ratio of the epoxy group of the epoxy resin to the reactive functional group of the first hardener reaches 1:1.2, the glass transition temperature of the electronic material prepared according to the present invention is high and holds steady (see Examples 1-2 to 1-4), while the glass transition temperature of the electronic material prepared using DCPD type ester hardener, by contrast, is unstable and significantly influenced by the amount of the hardener whether the ratio is above or below 1:1.2 (see Comparative Examples 1-1 to 1-3). Therefore, the formulation of the resin composition of the present invention is flexible and can be changed according to the situation.

### Embodiment 2: Effect of the Oligomeric Phosphonate

The resin compositions of Examples 2-1 to 2-3 and Comparative Examples 2-1 and 2-2 were prepared according to the constitutions shown in Table 2, wherein each components were mixed under room temperature with a stirrer, followed by adding toluene, methyl ethyl ketone, and γ-butyrolactone (all available from Fluka Company) thereinto, and after stirring the resultant mixture under room temperature for 60 to 120 minutes, the resin compositions were obtained.

The prepregs and metal-clad laminates of Examples 2-1 to 2-3 and Comparative Examples 2-1 and 2-2 were prepared using the above resin compositions according to the same procedure of Embodiment 1. The properties of the prepared prepregs and metal-clad laminates, including water absorption, solder resistance, peeling strength, glass transition temperature (Tg), thermal decomposition temperature (Td), flame retardance, dielectric constant (Dk) and dissipation factor (Df), were measured according to the aforementioned testing methods and the results are tabulated in Table 2.

TABLE 2

| | | Example | Example | Example | Comparative | Comparative |
|---|---|---|---|---|---|---|
| Unit: Parts by weight | | 2-1 | 2-2 | 2-3 | Example 2-1 | Example 2-2 |
| Epoxy resin | DNE-260 | 123 | 123 | 123 | 123 | 123 |
| | PNE-177 | 131.4 | 131.4 | 131.4 | 131.4 | 131.4 |
| First hardener | V575 | 275 | 275 | 275 | — | — |
| DCPD type | HPC-8000-65T | — | — | — | 472 | 472 |
| ester hardener | | | | | | |
| Flame retardant | OL-3001 | 120 | 98 | 75 | 118 | 80 |
| oligomeric | | | | | | |
| phosphonate | | | | | | |
| Catalyst | DMAP | 0.5 | 0.5 | 0.5 | 0.5 | 0.5 |
| Filler | 525ARI | 260 | 250 | 240 | 273 | 256 |

| Molar ratio (epoxy group of | 1:1.2 | 1:1.2 | 1:1.2 | 1:1.2 | 1:1.2 |
|---|---|---|---|---|---|
| epoxy resin:reactive | | | | | |
| functional group of first | | | | | |
| hardener or DCPD type | | | | | |
| ester hardener) | | | | | |
| Phosphorus content (wt %) | 2.0% | 1.7% | 1.4% | 1.9% | 1.4% |
| Filler content (wt %) | 30% | 30% | 30% | 30% | 30% |
| Gel time (S/G; sec) | 257 | 233 | 221 | 238 | 211 |
| Characteristics (Units) | | | | | |
| Water absorption (%) | 0.75 | 0.59 | 0.43 | 0.80 | 0.61 |
| Solder resistance (min) | >20 | >20 | >20 | >20 | >20 |
| Peeling strength (lb/inch) | 5.93 | 5.82 | 5.81 | 5.52 | 5.5 |
| DSC Tg (° C.) | 177 | 185 | 197 | 158 | 151 |
| Td 5% (° C.) | 364 | 372 | 380 | 360 | 371 |
| Flame retardance (UL-94) | V0 | V0 | V1 | V1 | V1 |
| DK @ 10 GHz (RC: 70%) | 3.8 | 3.7 | 3.7 | 3.8 | 3.7 |
| Df @ 10 GHz (RC: 70%) | 0.012 | 0.012 | 0.012 | 0.013 | 0.013 |

As shown in Table 2, the properties of the electronic materials of Examples 2-1 to 2-3, especially the glass transition temperature and peeling strength, are superior to those of the electronic materials of Comparative Examples 2-1 and 2-2. In particular, since the oligomeric phosphonate contains phosphorus which is capable of increasing flame retardance, when the resin composition of the present invention further comprises the oligomeric phosphonate, the electronic material prepared from such resin composition is provided with high glass transition temperature and excellent flame retardance, and the flame retardance of the electronic materials of Examples 2-1 and 2-2 even achieves UL-94 V0. Furthermore, when the ratio of the first hardener to the oligomeric phosphonate is about 2.8:1 (Example the resultant electronic material has high glass transition temperature, good flame retardance and low water absorption. The experiment data shown in Table 2 also indicates that a high phosphorus content in the resin composition will adversely affect the water absorption of the resultant electronic material.

### Embodiment 3: Effect of the Second Hardener

The resin compositions of Examples 3-1 to 3-3 and Comparative Examples 3-1 to 3-3 were prepared according to the constitutions shown in Table 3, wherein each components were mixed under room temperature with a stirrer, followed by adding toluene, methyl ethyl ketone, and γ-butyrolactone (all available from Fluka Company) thereinto, and after stirring the resultant mixture under room temperature for 60 to 120 minutes, the resin compositions were obtained.

The prepregs and metal-clad laminates of Examples 3-1 to 2-3 and Comparative Examples 3-1 and 3-3 were prepared using the above resin compositions according to the same procedure of Embodiment 1. The properties of the prepregs and the metal-clad laminates, including water absorption, solder resistance, peeling strength, glass transition temperature (Tg), thermal decomposition temperature (Td), flame retardance, dielectric constant (Dk) and dissipation factor (Df), were measured according to the aforementioned testing methods and the results are tabulated in Table 3.

TABLE 3

| | | Example | Example | Example | Comparative | Comparative | Comparative |
|---|---|---|---|---|---|---|---|
| Unit: Parts by weight | | 3-1 | 3-2 | 3-3 | Example 3-1 | Example 3-2 | Example 3-3 |
| Epoxy resin | DNE-260 | 123 | 123 | 123 | 123 | 123 | 123 |
| | PNE-177 | 131.4 | 131.4 | 131.4 | 131.4 | 131.4 | 131.4 |
| First hardener | V575 | 275 | 275 | 275 | — | — | — |
| DCPD type | HPC-8000-65T | — | — | — | 472 | 472 | 472 |
| ester hardener | | | | | | | |
| Flame retardant | OL-3001 | 98 | 98 | 98 | 102 | 102 | 102 |
| oligomeric | | | | | | | |
| phosphonate | | | | | | | |
| Cyanate resin | BA-230S | 65 | — | 33 | 65 | — | 33 |
| Benzoxazine | PF-3500 | — | 70 | 35 | — | 70 | 35 |
| resin | | | | | | | |
| Catalyst | DMAP | 0.5 | 0.5 | 0.5 | 0.5 | 0.5 | 0.5 |
| | Zinc | 0.024 | — | 0.012 | 0.024 | — | 0.012 |
| Filler | 525ARI | 270 | 270 | 270 | 286 | 285 | 285 |

| Molar ratio (epoxy group of | 1:1.2 | 1:1.2 | 1:1.2 | 1:1.2 | 1:1.2 | 1:1.2 |
|---|---|---|---|---|---|---|
| epoxy resin:reactive | | | | | | |
| functional group of first | | | | | | |
| hardener or DCPD type | | | | | | |
| ester hardener) | | | | | | |
| Phosphorus content (wt %) | 1.6% | 1.6% | 1.6% | 1.5% | 1.5% | 1.5% |
| Filler content (wt %) | 30% | 30% | 30% | 30% | 30% | 30% |
| Gel time (S/G; sec) | 221 | 234 | 227 | 201 | 206 | 210 |
| Characteristics (Units) | | | | | | |
| Water absorption (%) | 0.55 | 0.57 | 0.57 | 0.62 | 0.64 | 0.67 |
| Solder resistance (min) | >20 | >20 | >20 | >20 | >20 | >20 |
| Peeling strength (lb/inch) | 5.96 | 5.81 | 5.84 | 5.68 | 5.58 | 5.66 |
| DSC Tg (° C.) | 196 | 190 | 191 | 161 | 157 | 158 |
| Td 5% (° C.) | 375 | 375 | 375 | 365 | 362 | 365 |
| Flame retardance (UL-94) | V0 | V0 | V0 | V1 | V1 | V1 |
| Dk @ 10 GHz (RC: 70%) | 3.6 | 3.7 | 3.6 | 3.6 | 3.7 | 3.7 |
| Df @ 10 GHz (RC: 70%) | 0.009 | 0.012 | 0.011 | 0.011 | 0.014 | 0.013 |

As shown in Table 3, the properties of the electronic materials of Examples 3-1 to 3-3 are superior to those of the electronic materials of Comparative Examples 3-1 to 3-3. In particular, using cyanate resin and/or the benzoxazine resin in the resin composition of the present invention can further improve the glass transition temperature of the resultant electronic material. Under the same conditions, the glass transition temperature of the electronic material prepared using the resin composition of the present invention is up to 35 degrees Celsius higher than that of the electronic material prepared by the resin composition using the DCPD type ester hardener.

The above examples are used to illustrate the principle and efficacy of the present invention and show the inventive features thereof. People skilled in this field may proceed with a variety of modifications and replacements based on the disclosures and suggestions of the invention as described without departing from the principle and spirit thereof. Therefore, the scope of protection of the present invention is that as defined in the claims as appended.

What is claimed is:

1. A resin composition, comprising:
an epoxy resin having at least 2 epoxy groups in each molecule; and
a first hardener of formula (I): 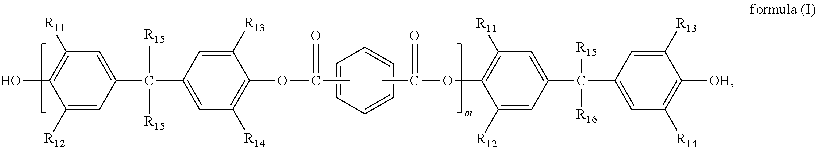
wherein, R₁₁, R₁₂, R₁₃, R₁₄, R₁₅ and R₁₆ are independently H, halogen, a C₁ to C₂₀ aliphatic hydrocarbyl group, a C₃ to C₂₀ alicyclic hydrocarbyl group, or a C₆ to C₂₀ aromatic hydrocarbyl group, and m is an integer from 1 to 10.

2. The resin composition of claim 1, wherein R₁₁, R₁₂, R₁₃, R₁₄, R₁₅ and R₁₆ are independently H, halogen, a C₁ to C₁₀ alkyl group, a C₃ to C₁₀ cycloalkyl group, or a C₆ to C₁₄ aromatic hydrocarbyl group.

3. The resin composition of claim 1, wherein R₁₁, R₁₂, R₁₃ and R₁₄ are each H, and R₁₅ and R₁₆ are each a methyl group.

4. The resin composition of claim 1, wherein the molar ratio of the epoxy group of the epoxy resin to the active functional group of the first hardener is from about 1:0.8 to about 1:1.6.

5. The resin composition of claim 1, wherein the molar ratio of the epoxy group of the epoxy resin to the active functional group of the first hardener is from about 1:1.2 to about 1:1.6.

6. The resin composition of claim 1, further comprising an oligomeric phosphonate of formula (II): 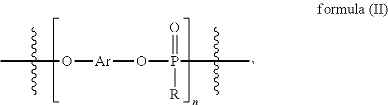
wherein, Ar is an aromatic group, and the —O—Ar—O— is a residue derived from a diphenol;
R is a C₁ to C₂₀ alkyl group, a C₂ to C₂₀ alkenyl group, a C₂ to C₂₀ alkynyl group, a C₃ to C₂₀ cycloalkyl group, or a C₆ to C₂₀ aryl group; and n is an integer from 1 to 20.

7. The resin composition of claim 6, wherein the diphenol is selected from the group consisting of resorcinol, hydroquinone, bisphenol A, bisphenol F, bisphenol S, 4,4′-thiodiphenol, oxydiphenol, phenolphthalein, 4,4′-(3,3,5-trimethyl-cyclohexane-1,1-diyl) diphenol, and combinations thereof.

8. The resin composition of claim 6, wherein the oligomeric phosphonate has the structure of formula (III): 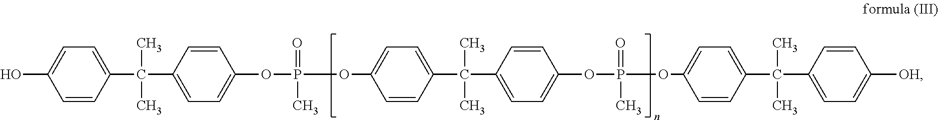
wherein, n is an integer from 1 to 10.

9. The resin composition of claim 1, further comprising a second hardener selected from the group consisting of cyanate ester resin, benzoxazine resin, phenol novolac resins (PN), styrene maleic anhydride resin (SMA), dicyandiamide (Dicy), diaminodiphenyl sulfone (DDS), amino triazine novolac resin (ATN), diaminodiphenylmethane, poly(styrene-co-vinyl phenol), and combinations thereof.

10. The resin composition of claim 6, further comprising a second hardener selected from the group consisting of cyanate ester resin, benzoxazine resin, phenol novolac resins (PN), styrene maleic anhydride resin (SMA), dicyandiamide (Dicy), diaminodiphenyl sulfone (DDS), amino triazine novolac resin (ATN), diaminodiphenylmethane, poly(styrene-co-vinyl phenol), and combinations thereof.

11. The resin composition of claim 1, further comprising a catalyst, which is an imidazole compound, a pyridine compound, or a combination thereof.

12. The resin composition of claim 6, further comprising a catalyst, which is an imidazole compound, a pyridine compound, or a combination thereof.

13. The resin composition of claim 1, further comprising a filler selected from the group consisting of silicon dioxide, aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartzs, diamonds, diamond-like, graphite, calcined kaolin, pryan, mica, hydrotalcite, hollow silicon dioxide, polytetrafluoroethylene (PTFE) powders, glass beads, ceramic whiskers, carbon nanotubes, nanosized inorganic powders, and combinations thereof.

14. The resin composition of claim 6, further comprising a filler selected from the group consisting of silicon dioxide, aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartzs, diamonds, diamond-like, graphite, calcined kaolin, pryan, mica, hydrotalcite, hollow silicon dioxide, polytetrafluoroethylene (PTFE) powders, glass beads, ceramic whiskers, carbon nanotubes, nanosized inorganic powders, and combinations thereof.

15. The resin composition of claim 1, further comprising a dispersant agent, a toughener, a flame retardant, or a combination of any two of more of the foregoing.

16. A prepreg, which is prepared by impregnating a substrate with the resin composition of claim 1 or by coating the resin composition of claim 1 onto a substrate and drying the impregnated or coated substrate.

17. A metal-clad laminate, which is prepared from the prepreg of claim 16.

18. A printed circuit board, which is prepared from the metal-clad laminate of claim 17.

19. A metal-clad laminate, which is prepared by directly coating the resin composition of claim 1 onto a metal foil and drying the coated metal foil.

20. A printed circuit board, which is prepared from the metal-clad laminate of claim 19.
